(19) United States
(12) Patent Application Publication
(10) Pub. No.: US 2023/0141520 A1
(43) Pub. Date: May 11, 2023

(54) Optical Receiver

(71) Applicant: Nippon Telegraph and Telephone Corporation, Tokyo (JP)

(72) Inventors: Yuki Yamada, Tokyo (JP); Masahiro Nada, Tokyo (JP); Shoko Tatsumi, Tokyo (JP); Hideaki Matsuzaki, Tokyo (JP)

(21) Appl. No.: 17/916,740

(22) PCT Filed: Apr. 23, 2020
(86) PCT No.: PCT/JP2020/017455

§ 371 Date: Oct. 3, 2022

(51) Int. Cl. G02B 19/00; H01L 27/144; H01L 31/0232; H01L 31/0304; H01L 31/105

(52) U.S. Cl. CPC G02B 19/0028; G02B 19/0076; H01L 27/1446; H01L 31/02327; H01L 31/03046; H01L 31/105; G02B 5/003

(57) ABSTRACT

A light-receiving device includes a light-receiving element formed on a main surface of a substrate, a light incidence surface formed on a side portion of the substrate at an acute angle or an obtuse angle with respect to the plane of the substrate and having an inclined surface forming one plane, and a lens for focusing light incident on the light-receiving element. The lens is disposed at a position where the light incident from the light incidence surface is reflected on a side of a back surface of the substrate.

### CROSS-REFERENCE TO RELATED APPLICATIONS

This application is a national phase entry of PCT Application No. PCT/JP2020/017455, filed on Apr. 23, 2020, which application is hereby incorporated herein by reference.

### TECHNICAL FIELD

The present disclosure relates to a light-receiving device composed of a semiconductor.

### BACKGROUND

A light-receiving element plays a role in converting an optical signal propagating in an optical fiber into an electrical signal in optical communications. With an increased communication capacity in data centers or the like in recent years, an increase in transmission capacity of an optical fiber communication system is awaited. This requires high-speed light-receiving elements to be used for optical fiber communication systems, and thus semiconductor light-receiving elements such as a photodiode (PD) are commonly used. This type of light-receiving element for optical communication generally uses a substrate composed of InP, on which a light-receiving layer composed of an InP-based compound semiconductor including a light-absorbing layer is formed. For example, InGaAs having a large light absorption coefficient in a communication wavelength band (1.55 μm or 1.3 μm) is used for the light-absorbing layer.

Because a light-receiving sensitivity of a common normal incidence PD as described in NPL 1 is determined by a light path length in a light-absorbing layer, high light-receiving sensitivity is generally achieved by increasing the thickness of the light-absorbing layer. On the other hand, a band of the PD is determined by a carrier transit time, an element capacitance, a resistance, and the like, and increasing the thickness of the light-absorbing layer increases the carrier transit time, causing a decrease in the band. As described above, a normal incidence type PD has a trade-off relationship between a light-receiving sensitivity and a band.

To solve this issue, an oblique incidence light-receiving device has been proposed, in which light is incident on a light-receiving layer from an oblique direction and propagated obliquely with respect to a lamination direction of a light-absorbing layer (NPL 2).

This oblique incidence light-receiving device will be described with reference to FIG. 11. The light-receiving device includes a light-receiving element in which a first contact layer 302 composed of InGaAsP or the like, a light-absorbing layer 303 composed of InGaAs, and a second contact layer 304 composed of InGaAsP or the like are laminated in this order on an InP substrate 301. A first electrode 311 is connected to the first contact layer 302, and a second electrode 312 is connected to the second contact layer 304.

Further, the light-receiving device includes a facet surface 305 in a direction of (1, −1, −1) on a side surface of the InP substrate 301 by a method, such as wet etching. Light incident on the facet surface 305 from a lateral direction is incident on a side of a back surface (the first contact layer 302) of the light-receiving element at an incident angle of 65° and is incident on the light-absorbing layer 303 at an incident angle of 54°. As a result, a light path length is increased by 1.7 times as compared with that of a normal incidence light-receiving device, and thus a significant increase in sensitivity can be expected.

### CITATION LIST

### Non Patent Literature

NPL 1: M. Nada et al., “Inverted InAlAs/InGaAs Avalanche Photodiode with Low-High-Low Electric Field Profile”, Japanese Journal of Applied Physics, vol. 51, 02BG03, 2012.

NPL 2: Y. Hirota et al., “Reliable non-Zn-diffused InP/InGaAs avalanche photodiode with buried n-InP layer operated by electron injection mode”, Electronics Letters, vol. 40, no. 21, pp. 2004.

### SUMMARY

### Technical Problem

Because light propagates obliquely in the light-receiving element (light-absorbing layer) in the oblique incidence light-receiving device described above, the beam spot of the light propagating in the light-receiving element including the light-absorbing layer is expanded as compared with that of a normal incidence light-receiving device. To prevent a decrease in sensitivity due to incident light leakage caused by expansion of the beam spot, it is necessary to increase the area in a plan view of a light propagation path (light-absorbing layer) in the light-receiving element depending on the above-described beam spot. However, the increase in the area of the light-receiving element causes an increase in the operation area of the light-receiving element, thus decreasing the band due to an increase in an element capacitance. For example, an existing oblique incidence structure as illustrate in FIG. 11 has the size in a plan view of the beam spot in the first contact layer 302, in which the length in an incident direction (x direction) is 2.9 times larger than that in a y direction perpendicular to the incident direction.

It is a common technique to reduce the spot size of incident light by using an external lens and achieve an optical coupling with little loss for an element having a small light-receiving area when signal light is incident on a light-receiving element, and the spot size of incident light in a normal incidence structure can be reduced to about 10 μm. However, the beam spot cannot be further narrowed with an external lens having a long focal length, and the oblique incidence structure illustrated in FIG. 11 allows the spot size of incident light to be reduced only to about 29 μm×10 μm. This makes it difficult to reduce the size of a light-receiving element.

As described above, the beam spot of light incident on the light-receiving element is expanded in the light-receiving device having an oblique incidence structure. This makes it difficult to reduce the size of the light-receiving element and achieve high speed operation.

The present disclosure has been made to solve the above-described issue, and an object thereof is to allow for further reducing the size of a light-receiving element without causing a decrease in band in a light-receiving device having an oblique incidence structure.

### Means for Solving the Problem

A light-receiving device according to the present disclosure includes a light-receiving element formed on a main surface of a substrate, a light incidence surface formed on a side portion of the substrate at an acute angle or an obtuse angle with respect to a plane of the substrate and having an inclined surface forming one plane, and a lens for focusing light incident on the light-receiving element. The light-receiving element includes a back surface incidence photodiode including a first semiconductor layer formed on the substrate and composed of a first conductivity type semiconductor, a light absorbing layer formed on the first semiconductor layer and composed of a semiconductor, a second semiconductor layer formed on the light-absorbing layer and composed of a second conductivity type semiconductor, a first electrode connected to the second semiconductor layer, and a second electrode connected to the first semiconductor layer. Light incident from the light incidence surface is reflected on a side of a back surface of the substrate and is incident on the light-receiving element obliquely with respect to a plane of the light-absorbing layer.

### Effects of Embodiments of the Invention

As described above, according to the present disclosure, since the lens is provided to focus the light which is incident from the light incidence surface formed on the side portion of the substrate at an acute angle or an obtuse angle with respect to the plane of the substrate on which the light-receiving element is formed and is incident on the light-receiving element, the size of the light-receiving element can be further reduced without causing a decrease in band in the light-receiving device having the oblique incidence structure.

### BRIEF DESCRIPTION OF THE DRAWINGS

FIG. 1 is a cross-sectional view illustrating a configuration of a light-receiving device according to a first embodiment of the present disclosure.

FIG. 2A is a perspective view illustrating part of a configuration of a light-receiving device according to the first embodiment of the present disclosure.

FIG. 2B is a plan view (FIG. 2B(a)) and side views (FIGS. 2B(b) and (c)) illustrating part of a configuration of a light-receiving device according to the first embodiment of the present disclosure.

FIG. 3 is a plan view (FIG. 3(a)) and side views (FIGS. 3(b) and (c)) illustrating part of a configuration of a light-receiving device according to a second embodiment of the present disclosure.

FIG. 4 is a perspective view illustrating a configuration of a light-receiving device according to a third embodiment of the present disclosure.

FIG. 5 is a perspective view illustrating a configuration of a light-receiving device according to a fourth embodiment of the present disclosure.

FIG. 6 is a cross-sectional view illustrating a configuration of a light-receiving device according to a fifth embodiment of the present disclosure.

FIG. 7 is a cross-sectional view illustrating a configuration of a light-receiving device according to a sixth embodiment of the present disclosure.

FIG. 8 is a cross-sectional view illustrating a configuration of a light-receiving device according to a seventh embodiment of the present disclosure.

FIG. 9 is a cross-sectional view illustrating a configuration of a light-receiving device according to the seventh embodiment of the present disclosure.

FIG. 10 is a cross-sectional view illustrating a configuration of a light-receiving device according to an eighth embodiment of the present disclosure.

FIG. 11 is a cross-sectional view illustrating a configuration of an oblique incidence light-receiving device.

### DETAILED DESCRIPTION OF ILLUSTRATIVE EMBODIMENTS

Hereinafter, a light-receiving device according to an embodiment of the present disclosure will be described.

### First Embodiment

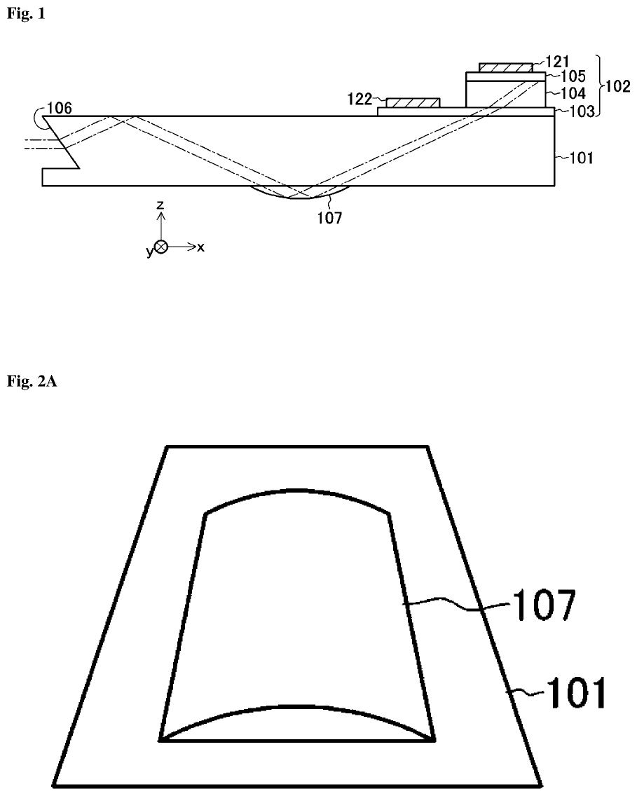

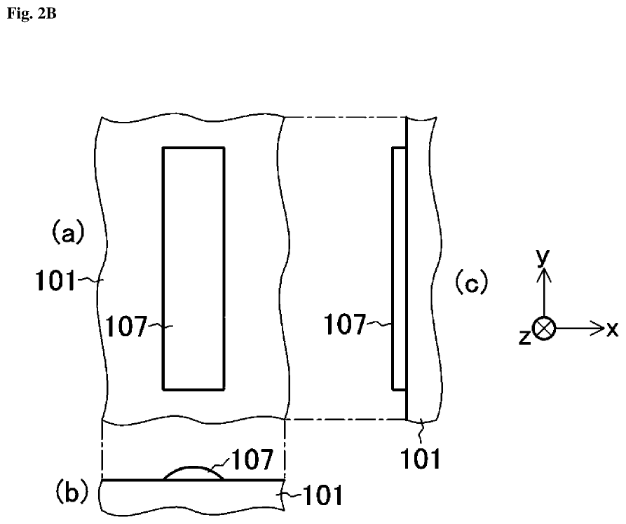

First, a light-receiving device according to the first embodiment of the present disclosure will be described with reference to FIGS. 1, 2A and 2B. The light-receiving device includes a light-receiving element 102 formed on a main surface of a substrate 101, a light incidence surface 106 which is formed on a side portion of the substrate 101 at an acute angle or an obtuse angle with respect to a plane of the substrate 101 and is composed of an inclined surface forming one plane, and a lens 107 for focusing light incident on the light-receiving element 102.

The substrate 101 is composed of, for example, InP. The light-receiving element 102 includes a first semiconductor layer 103 which is formed on the substrate 101 and is composed of a first conductivity type semiconductor, a light-absorbing layer 104 which is formed on the first semiconductor layer 103 and is composed of a semiconductor, and a second semiconductor layer 105 which is formed on the light-absorbing layer 104 and is composed of a second conductivity type semiconductor. The light-receiving element 102 is a so-called back surface incidence type photodiode.

The first semiconductor layer 103 is composed of, for example, a first conductivity type (n type, for example) InGaAsP. The light-absorbing layer 104 is composed of i-InGaAs. The second semiconductor layer 105 is composed of a second conductivity type (p type, for example) InGaAsP.

Further, the light-receiving element 102 includes a first electrode 121 connected to the second semiconductor layer 105 and a second electrode 122 connected to the first semiconductor layer 103. These electrodes can be composed of a laminated metal structure made of Ti/Pt/Au, for example.

In the light-receiving device according to the first embodiment, the light incident from the light incidence surface 106 is reflected on a side of a back surface of the substrate 101 and is incident on the light-receiving element 102 obliquely with respect to a plane of the light-absorbing layer 104. In the first embodiment, the angle between the main surface of the substrate 101 in the region where the light-receiving element 102 is formed and the light incidence surface 106 is an acute angle, and the light incident from the light incidence surface 106 is reflected on a side of the main surface of the substrate 101, reflected on the side of the back surface of the substrate 101, and then incident on the light-receiving element 102. In the first embodiment, the lens 107 is disposed at a position where the light incident from the light incidence surface 106 is reflected on the side of the back surface of the substrate 101.

Further, in the first embodiment, the lens 107 has a curvature in an incident direction of the light incident from the light incidence surface 106 (x direction), and has a shape similar to a so-called cylindrical lens.

In the light-receiving device according to the first embodiment having the structure described above, the light incident from the light incidence surface 106 in a state of being parallel to the plane of the substrate 101 is refracted by the light incidence surface 106 to change the traveling direction of the light on a plane (xz plane) parallel to a plane perpendicular to the plane of the substrate 101, and is reflected by the main surface of the substrate 101 to change the traveling direction of the light again on the xz plane. Then, the light is reflected by the surface of the lens 107 to change the traveling direction of the light at the third time on the xz plane and is obliquely incident on the back surface of the light-receiving element 102. Here, because the lens 107 has a curvature in the x direction and has a capability to focus light in the x direction, the light reflected by the surface of the lens 107 can form a spot of the light passing through the light-receiving element 102 into a perfect circle shape.

Specific curvature and focal length of the lens 107 are arbitrary design items because they also depend on an optical system on an incident side, but the lens 107 can be designed so that the focal length is equivalent to the thickness of the substrate 101. In order to reduce the spot size in the x direction to one third or less, the thickness of the substrate 101 is preferably 150 μm or less.

According to the first embodiment, as described above, the expansion of the spot due to the use of the oblique incidence structure can be reduced, and high-speed operation with a downsized light-receiving element can be achieved.

First, the first semiconductor layer 103, the light-absorbing layer 104, and the second semiconductor layer 105 are caused to undergo crystal growth on the substrate 101 composed of InP. Each semiconductor layer may be grown using, for example, a well-known metal-organic chemical vapor deposition (MOCVD) method. Subsequently, the first semiconductor layer 103, the light-absorbing layer 104, and the second semiconductor layer 105 are processed into a mesa shape by the publicly known photolithographic technique and an etching technique. Then, the first electrode 121 and the second electrode 122 are formed by a manufacturing technique such as vapor deposition, lift-off, or the like.

Next, a protective film which covers the light-receiving element 102 and has an opening in a region of the substrate 101 where the light incidence surface 106 is to be formed is formed by the publicly known photolithographic technique, and the substrate 101 is selectively etched by wet etching using the formed protective film as a mask and hydrochloric acid as an etchant. For example, the main surface of the substrate 101 composed of InP is a (001) surface, and the side wall of the substrate 101 is a (−110) surface. By anisotropically etching the portion of the side surface of the substrate 101 where the protective film is opened with the above-described wet etching, the (1, −1, −1) surface of InP is exposed, that is, a facet surface in the (1, −1, −1) direction is formed, and the light incidence surface 106 is formed.

Next, the substrate 101 is thinned from the side of the back surface by a well-known polishing technique such as mechanical polishing, and then the lens 107 is formed in a predetermined position on the back surface of the substrate 101. The lens 107 may be formed by using, for example, such a resist pattern transfer technique as described in the reference document. First, a so-called positive photoresist composed of, for example, a novolac resin is applied to the back surface of the substrate 101 to form a resist layer. Next, the formed resist layer is exposed and developed by the publicly known lithographic technique to form a cuboid resist pattern having a rectangular shape in a plan view.

Next, the formed resist pattern is reflowed by heating to, for example, 100° C. to 200° C. By this heat treatment, the resist pattern has a shape obtained by cutting out a part of a cylinder. Next, using the reflowed resist pattern as a mask, the back surface of the substrate 101 is etched by a dry etching technique having perpendicular anisotropy such as reactive ion etching under the processing conditions such that the resist pattern and the substrate 101 have the same etching rate. By this etching treatment, the shape of the reflowed resist pattern can be formed on the back surface of the substrate 101, and the lens 107 similar to a cylindrical lens can be obtained.

### Second Embodiment

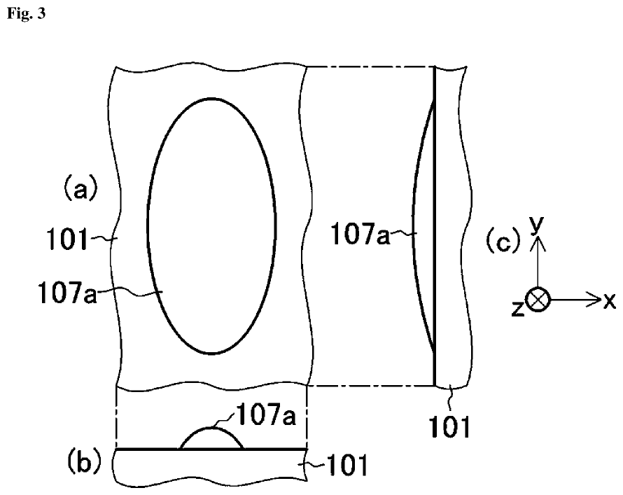

Next, a light-receiving device according to the second embodiment of the present disclosure will be described with reference to FIG. 3. In the first embodiment described above, the lens 107 is a so-called cylindrical lens having a curvature in the incident direction of the light incident from the light incidence surface 106 (x direction), but the present disclosure is not limited thereto. For example, a lens 107a having a curvature in the incident direction of the light incident from the light incidence surface 106 (x direction) as well as in a direction perpendicular to the incident direction of the light incident from the light incidence surface 106 (y direction) in a plane parallel to the plane of the substrate 101 can be also disposed (formed) on the back surface of the substrate 101. The curvature in the incident direction (x direction) and the curvature in the direction perpendicular to the incident direction (y direction) are different from each other. Other configurations are similar to the configurations of the first embodiment described above.

As described in the first embodiment, when the lens 107 similar to a cylindrical lens is used, it is difficult to focus the spot in the y direction on the light-receiving element 102 in a plan view to a size of 10 μm or less, and the same applies to the case where an external lens (external optical system) having a long focal length is used. Thus, there is a room for improvement in increasing speed by reducing element size. In contrast, by using the lens 107a according to the second embodiment, it is possible to reduce the spot size while maintaining the spot shape on the light-receiving element in a perfect circular shape.

Specific curvature and focal length of the lens 107a are arbitrary design items because they also depend on an external optical system on an incident side, but the lens 107a can be formed so that the focal length is equivalent to the thickness of the substrate 101. In order to reduce the spot size in the x direction and the y direction to 10 μm or less, the thickness of the substrate 101 is preferably 150 μm or less.

According to the second embodiment, as described above, the expansion of the spot due to the use of the oblique incidence structure can be reduced, and high-speed operation with a downsized light-receiving element can be achieved. Although the second embodiment has been described with reference to the lens 107a having an elliptical shape in a plan view, the spot size can be reduced even when a lens having a perfect circular shape in a plan view is used. However, in that case, the spot shape of light in the plan view on the light-receiving element 102 is elliptical. Note that the lens 107a can be formed in the same manner as the lens 107 described above. The lens 107a may be formed by forming a resist pattern having an elliptical shape in a plan view and reflowing it.

### Third Embodiment

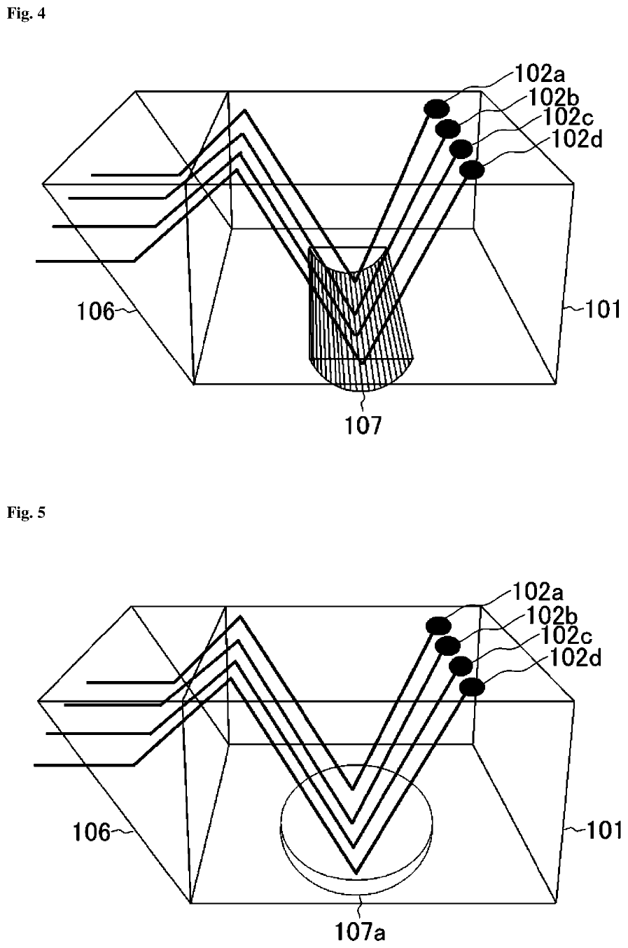

Next, a light-receiving device according to the third embodiment of the present disclosure will be described with reference to FIG. 4. In the light-receiving device according to the third embodiment, a plurality of light-receiving elements 102a, 102b, 102c and 102d are formed on the main surface of the substrate 101. Each of the light-receiving elements 102a, 102b, 102c and 102d is identical to the light-receiving element 102 according to the first embodiment described above. The light-receiving elements 102a, 102b, 102c and 102d are arranged on a straight line extending in the y direction perpendicular to the incident direction on the main surface of the substrate 101. Incident light is incident on each of the light-receiving elements 102a, 102b, 102c and 102d.

When the plurality of light-receiving elements 102a, 102b, 102c and 102d are provided on the main surface of the substrate 101, the length of the lens 107 in they direction is longer than the arrangement length of the plurality of light-receiving elements 102a, 102b, 102c and 102d. With this configuration, incident light can be focused by one lens 107 to each of the plurality of light-receiving elements 102a, 102b, 102c and 102d. In this configuration, even with the plurality of light-receiving elements 102a, 102b, 102c and 102d, it is not necessary to form a plurality of lenses, and thus manufacturing is facilitated. In addition, light can be focused by the same lens 107, and thus characteristics variations between the light-receiving elements 102a, 102b, 102c and 102d can be reduced.

In addition, according to the third embodiment, because an oblique incidence structure is used as with embodiments 1 to 3 described above, the expansion of the spot can be reduced, and high-speed operation with a downsized light-receiving element can be achieved.

### Fourth Embodiment

Next, the fourth embodiment of the present disclosure will be described with reference to FIG. 5. In the light-receiving device according to the fourth embodiment, the plurality of light-receiving elements 102a, 102b, 102c and 102d are formed on the main surface of the substrate 101. These configurations are similar to those of the third embodiment described above. In the fourth embodiment, the lens 107a having a curvature in the x direction as well as in the y direction is used.

According to the fourth embodiment, there is an advantage that intervals between light-receiving elements are not limited by the size of a lens, as compared with a configuration in which the same number of light-receiving elements and lenses are provided.

### Fifth Embodiment

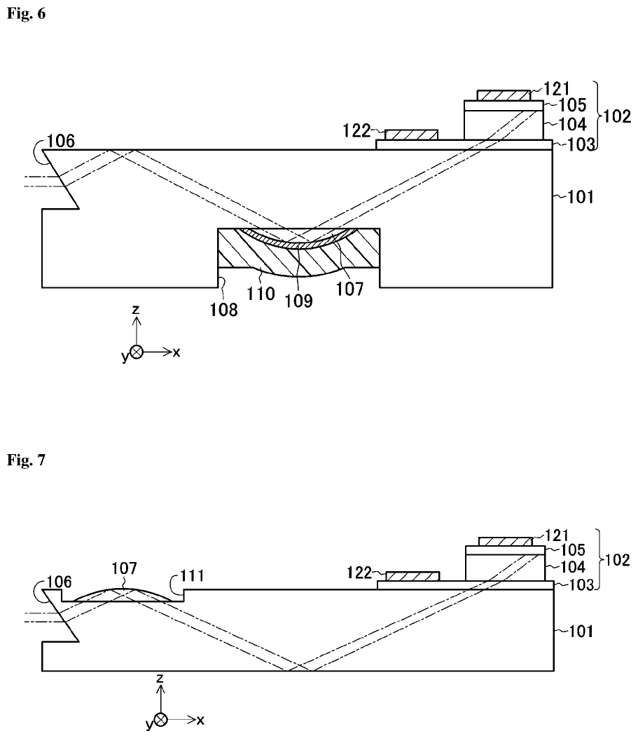

Next, the fifth embodiment of the present disclosure will be described with reference to FIG. 6. The light-receiving device according to the fifth embodiment includes a recessed portion 108 formed on the back surface of the substrate 101. The recessed portion 108 is, for example, a groove extending in a direction (the y direction) perpendicular to the incident direction (the x direction). In the fifth embodiment, the lens 107 is formed on the bottom surface of the recessed portion 108. Further, in the fifth embodiment, a metal layer 109 formed to cover the surface of the lens 107 is provided. The metal layer 109 functions as a mirror. Furthermore, in the fifth embodiment, a protective film no is provided to protect the lens 107 on which the metal layer 109 is formed. Other configurations are similar to the configurations of the first embodiment described above.

In mounting the light-receiving device on a module, there is a possibility that the lens 107 may be damaged to cause a reduction in reflectance by the contact between a package substrate or the like and the back surface of the substrate 101. By forming the recessed portion 108 and providing the lens 107 on the bottom portion thereof, it is possible to prevent the lens from coming into contact with other parts in mounting. In addition, by forming the protective film 110, an effect of preventing the surface of the lens 107 from being scratched or being contaminated with impurities can be expected. The protective film 110 can be composed of a resin, for example. The protective film 110 can also be composed of SiN, SiO₂, or the like.

However, when the protective film 110 is formed, there is a possibility that a refractive index difference with respect to the lens 107 may decrease and the reflectance on the surface of the lens 107 may decrease. For example, at the interface between InP (refractive index: 3.2) and air (refractive index: 1.0), total reflection occurs at an incident angle of 18° or greater. On the other hand, at the interface between InP and SiN (refractive index: 2.0), total reflection occurs at an incident angle of 39° or greater. In this way, there is a concern that reflectance may decrease by forming the protective film 110. In contrast, by forming the metal layer 109, an effect of preventing a decrease in reflectance at the surface of the lens 107 is produced.

In the fifth embodiment, as in embodiments 1 to 4 described above, the expansion of the spot due to the use of an oblique incidence structure can be reduced, and high speed operation with a downsized light-receiving element can be achieved. Note that, the structure of the light-receiving device according to the fifth embodiment can be made by forming the recessed portion 108 before forming the lens 107 described in the first embodiment. The recessed portion 108 can be formed by the publicly known lithographic technique and a dry etching technique. Further, after the lens 107 is formed, the metal layer 109 can be formed by depositing Au or the like with a deposition technique such as vapor deposition. Furthermore, after the metal layer 109 is formed, the protective film no can be formed by depositing SiN, SiO₂, or the like with a deposition technique such as chemical vapor deposition.

### Sixth Embodiment

Next, the sixth embodiment of the present disclosure will be described with reference to FIG. 7. In the light-receiving device according to the seventh embodiment, the lens 107 is formed on the main surface of the substrate 101. In the sixth embodiment, a recessed portion 111 is formed on the main surface of the substrate 101, and the lens 107 is formed on the bottom surface of the recessed portion 108. The lens 107 is disposed at a position where the light incident from the light incidence surface 106 is reflected on the main surface side of the substrate 101. Other configurations are similar to the configurations of the first embodiment described above.

In the light-receiving device according to the sixth embodiment having the structure described above, the light incident from the light incidence surface 106 in a state of being parallel to the plane of the substrate 101 is refracted by the light incidence surface 106 to change the traveling direction of the light on a plane (xz plane) parallel to a plane perpendicular to the plane of the substrate 101. Subsequently, the light is reflected by the surface of the lens 107 on the main surface side of the substrate 101 to change the traveling direction of the light again on the xz plane. Then, the light is reflected by the back surface of the lens 107 to change the traveling direction of the light at the third time on the xz plane and is obliquely incident on the back surface of the light-receiving element 102. Here, because the lens 107 has a curvature in the x direction and has a capability to focus light in the x direction, the light reflected by the surface of the lens 107 can form a spot of the light passing through the light-receiving element 102 into a perfect circle shape.

According to the sixth embodiment, the recessed portion in and the lens 107 are formed on the front surface side of the substrate 101 on which the light-receiving element 102 is formed. Thus, for example, in the lithographic technique for forming the recessed portion 111 and the lens 107, alignment of exposure on the side of the back surface of the substrate 101 is not necessary, and the light-receiving device can be manufactured without a complicated process. In addition, because thinning of the substrate 101 can be performed after the formation of the lens 107, the lens 107 can be formed on the substrate 101 being thick and having a high mechanical strength.

In the sixth embodiment, as in embodiments 1 to 5 described above, the expansion of the spot due to the use of an oblique incidence structure can be reduced, and high speed operation with a downsized light-receiving element can be achieved. By the way, the substrate 101 can also be composed of a material different from the InP-based compound semiconductor constituting the light-receiving element. The substrate 101 can be composed of Si, for example. Si has a higher processability by dry etching than a material system such as InP, and thus makes it easier to form lenses. Thus, the light-receiving device can be made with a higher processing accuracy.

For example, after the light-receiving element 102 is formed on a growth substrate composed of InP or the like, the growth substrate is thinned by mechanical polishing or the like. Subsequently, a substrate made of silicon is attached to the thinned growth substrate to form the substrate 101. Then, the recessed portion and the lens are formed as described above. In addition, the lens does not need to be composed of the same material as the substrate, that is, a lens formed of a material system such as glass can be attached onto a predetermined location.

### Seventh Embodiment

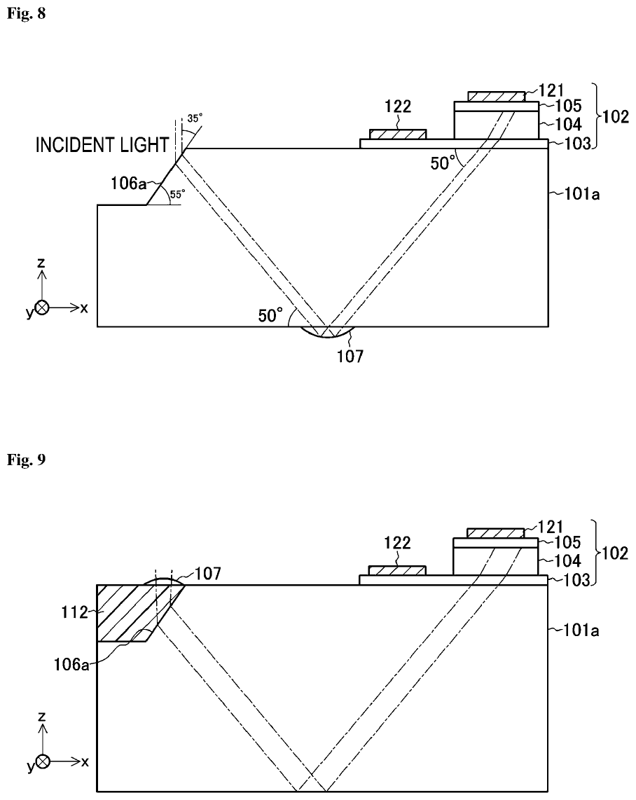

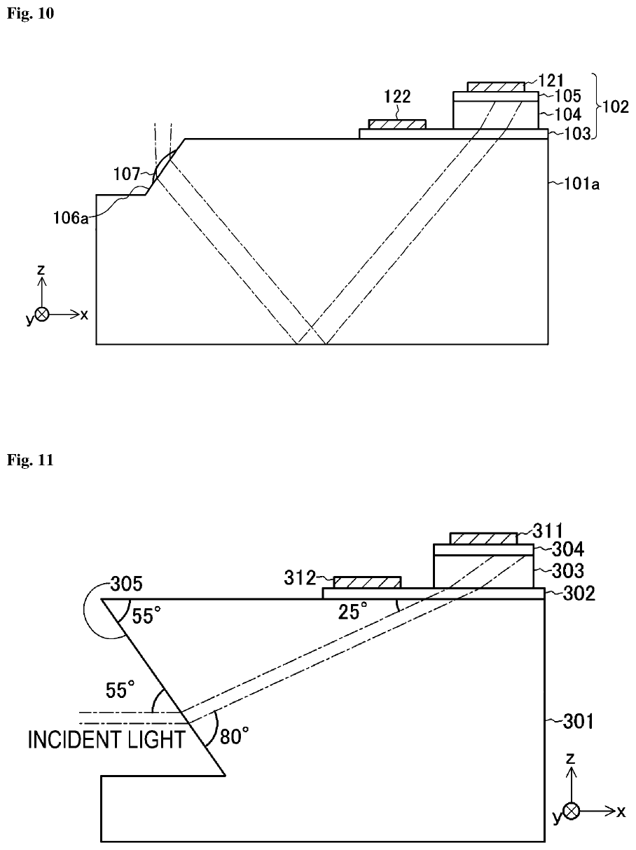

Next, the seventh embodiment of the present disclosure will be described with reference to FIG. 8. In the light-receiving device according to the eighth embodiment, an angle between the main surface of a substrate 101 in a region where the light-receiving element 102 is formed and a light incidence surface 106a is an obtuse angle. In the seventh embodiment, the light incidence surface 106a is formed to face the front surface side of the substrate 101a. Thus, in the seventh embodiment, incident light is incident on the light incidence surface 106a from above the substrate 101a.

In the seventh embodiment, the light incident from the light incidence surface 106a is reflected on a side of a back surface of the substrate 101a and is incident on the light-receiving element 102, and the lens 107 is disposed at a position where the light incident from the light incidence surface 106a is reflected on the side of the back surface of the substrate 101a. Other configurations are similar to the configurations of the first embodiment described above.

In the seventh embodiment, when the lens 107 is not used, the spot size on the light-receiving element 102 can be reduced only to 23 μm×10 μm, and thus it is difficult to reduce the operating area of the light-receiving element 102. On the other hand, by providing the lens 107, an effect of reducing the expansion of the spot size can be expected.

In addition, in the seventh embodiment, it is not necessary to form a side surface of the substrate 101a by cleavage or the like at a predetermined distance from the location of the light-receiving element 102. This is because the light incidence surface 106a faces the front surface side of the substrate 101a. Thus, light can be incident on the light-receiving element 102 without forming the side surface at a predetermined position by cleavage after the light-receiving element 102 is formed on the substrate 101a. Consequently, characteristics evaluation can be done in a wafer form. The light incidence surface 106a can be formed with an etching technique such as wet etching by using, for example, a facet surface of InP in a (1, 1, 1) direction.

### Eighth Embodiment

Next, the eighth embodiment of the present disclosure will be described with reference to FIG. 9. In the light-receiving device according to the eighth embodiment, an angle between the main surface of the substrate 101a in a region where the light-receiving element 102 is formed and the light incidence surface 106a is an obtuse angle. In the eighth embodiment, the light incidence surface 106a is formed to face the front surface side of the substrate 101a. Thus, in the eighth embodiment, incident light is incident on the light incidence surface 106a from above the substrate 101a. These configurations are similar to those of the seventh embodiment described before.

In the eighth embodiment, the light incident from the light incidence surface 106 is reflected on a side of a back surface of the substrate 101 and is incident on the light-receiving element 102, and the lens 107 is disposed on the incident side of the light incident from the light incidence surface 106a. In the eighth embodiment, a protective film 112 is provided to cover the light incidence surface 106a, and the lens 107 is disposed on the protective film 112. The protective film 112 can be composed of a resin, or an insulation material such as SiN and SiO₂, for example. In the present example, the surface of the protective film 112 on which the lens 107 is formed forms the same plane as the main surface of the substrate 101a.

According to the eighth embodiment, because the light incidence surface 106a is protected by the protective film 112, an effect of preventing the light incidence surface 106a from being scratched or being contaminated with impurities can be expected. In addition, in the eighth embodiment, because the oblique incidence structure is used as with embodiments 1 to 7 described above, the expansion of the spot can be reduced, and high-speed operation with a downsized light-receiving element can be achieved.

### Ninth Embodiment

Next, a ninth embodiment of the present disclosure will be described with reference to FIG. 10. In the light-receiving device according to the ninth embodiment, an angle between the main surface of the substrate 101a in a region where the light-receiving element 102 is formed and the light incidence surface 106a is an obtuse angle. In the ninth embodiment, the light incidence surface 106a is formed to face the front surface side of the substrate 101a. Thus, in the ninth embodiment, incident light is incident on the light incidence surface 106a from above the substrate 101a. These configurations are similar to those of the seventh embodiment described before.

In the ninth embodiment, the light incident from the light incidence surface 106 is reflected on a side of a back surface of the substrate 101 and is incident on the light-receiving element 102, and the lens 107 is disposed on the incident side of the light incident from the light incidence surface 106a. In the ninth embodiment, the lens 107 is disposed on the light incidence surface 106a. Other configurations are similar to the configurations of the ninth embodiment described above. The lens 107 is composed of, for example, a material such as Si, and attached to the light incidence surface 106a. In the ninth embodiment, because the oblique incidence structure is used as with the first to eighth embodiments described above, the expansion of the spot can be reduced, and high-speed operation with a downsized light-receiving element can be achieved.

Note that, although InP or Si is used as the substrate in the above description, the substrate is not limited thereto and can be composed of SiC, GaN, glass, or the like. In addition, although the case where the light-absorbing layer is composed of InGaAs has been described, the light-absorbing layer is not limited thereto and can be composed of other semiconductors such as Ge.

Light may be incident from the top surface or the back surface of the light-receiving element, or can be incident from a side surface, or can be incident from an oblique direction.

Besides, although the method using a facet surface for forming the light incidence surface has been described, the method is not limited thereto, and the light incidence surface can be formed by an arbitrary processing method such as dicing. Further, a spherical or an aspherical lens, or a Fresnel lens may be used as the lens. Furthermore, an anti-reflective layer may be formed on the light incidence surface. In addition, in the light-receiving element, it is within the scope of general design to provide a mirror on the upper side (on the second semiconductor layer) for increasing a light path length of the light passing through the light-receiving element. Moreover, although a so-called Pin-type photodiode has been described as an example in the above description, the light-receiving element may be composed of an avalanche photodiode.

As described above, according to the present disclosure, because the lens is provided to focus the light incident from the light incidence surface formed on the side portion of the substrate at an acute angle or an obtuse angle with respect to the plane of the substrate on which the light-receiving element is formed and incident on the light-receiving element, the size of the light-receiving element can be further reduced without causing a decrease in band in the light-receiving device having the oblique incidence structure.

Meanwhile, the present disclosure is not limited to the embodiments described above, and it will be obvious to those skilled in the art that various modifications and combinations can be implemented within the technical idea of the present disclosure.

[Reference] O. Wada, “Ion-Beam Etching of InP and Its Application to the Fabrication of High Radiance InGaAsP/InP Light Emitting Diodes”, J. Electrochem. Soc., vol. 131, no. 10, pp. 2373-2380, 1984.

### REFERENCE SIGNS LIST

101 Substrate

102 Light-receiving element

103 First semiconductor layer

104 Light-absorbing layer

105 Second semiconductor layer

106 Light incidence surface

107 Lens

121 First electrode

122 Second electrode.

1-8. (canceled)

9. A light-receiving device comprising:
a light-receiving element on a main surface of a substrate, the light-receiving element including a back surface incidence photodiode including:
a first semiconductor layer on the substrate and composed of a first conductivity type semiconductor;
a light-absorbing layer on the first semiconductor layer and composed of a semiconductor;
a second semiconductor layer on the light-absorbing layer and composed of a second conductivity type semiconductor;
a first electrode connected to the second semiconductor layer; and
a second electrode connected to the first semiconductor layer;
a light incidence surface on a side portion of the substrate at an acute angle or an obtuse angle with respect to a plane of the substrate and having an inclined surface forming one plane; and
a lens configured to focus light incident on the light-receiving element, wherein light incident from the light incidence surface is reflected on a back surface side of the substrate and is incident on the light-receiving element obliquely with respect to a plane of the light-absorbing layer.

10. The light-receiving device according to claim 9, wherein
the lens has a curvature in an incident direction of the light incident from the light incidence surface.

11. The light-receiving device according to claim 10, wherein the lens has a curvature in a direction perpendicular to the incident direction of the light incident from the light incidence surface in a plane parallel to the plane of the substrate, and the curvature in the incident direction and the curvature in the direction perpendicular to the incident direction are different from each other.

12. The light-receiving device according to claim 9, wherein:
an angle between the main surface of the substrate in a region where the light-receiving element is disposed and the light incidence surface is an acute angle;
the light incident from the light incidence surface is reflected on a main surface side of the substrate, reflected on the back surface side of the substrate, and then incident on the light-receiving element; and
the lens is disposed at a position where the light incident from the light incidence surface is reflected on the main surface side of the substrate or a position where the light incident from the light incidence surface is reflected on the back surface side of the substrate.

13. The light-receiving device according to claim 9, wherein:
an angle between the main surface of the substrate in a region where the light-receiving element is disposed and the light incidence surface is an obtuse angle;
the light incident from the light incidence surface is reflected on the back surface side of the substrate and then incident on the light-receiving element; and
the lens is disposed at a position where the light incident from the light incidence surface is reflected on the back surface side of the substrate or disposed on an incident side of the light incident from the light incidence surface.

14. The light-receiving device according to claim 9, wherein the lens is formed on a bottom surface of a recess on the substrate.

15. The light-receiving device according to claim 9, further comprising:
a metal layer formed covering a surface of the lens.

16. The light-receiving device according to claim 9, wherein:
a plurality of light-receiving elements are disposed on the main surface of the substrate, the plurality of light-receiving elements comprising the light-receiving element.

17. A light-receiving device comprising:
a light-receiving element on a main surface of a substrate, the light-receiving element including a back surface incidence photodiode, the back surface incidence photodiode comprises a light-absorbing layer composed of a semiconductor;
a light incidence surface on a side portion of the substrate at an acute angle or an obtuse angle with respect to a plane of the substrate and having an inclined surface forming one plane; and
a lens configured to focus light incident on the light-receiving element, wherein light incident from the light incidence surface is reflected on a back surface side of the substrate and is incident on the light-receiving element obliquely with respect to a plane of the light-absorbing layer.

18. The light-receiving device according to claim 17, wherein the back surface incidence photodiode comprises:
a first semiconductor layer on the substrate and composed of a first conductivity type semiconductor, wherein the light-absorbing layer is disposed on the first semiconductor layer; and
a second semiconductor layer on the light-absorbing layer and composed of a second conductivity type semiconductor.

19. The light-receiving device according to claim 17, wherein
the lens has a curvature in an incident direction of the light incident from the light incidence surface.

20. The light-receiving device according to claim 19, wherein the lens has a curvature in a direction perpendicular to the incident direction of the light incident from the light incidence surface in a plane parallel to the plane of the substrate, and the curvature in the incident direction and the curvature in the direction perpendicular to the incident direction are different from each other.

21. The light-receiving device according to claim 17, wherein:
an angle between the main surface of the substrate in a region where the light-receiving element is disposed and the light incidence surface is an acute angle;
the light incident from the light incidence surface is reflected on a main surface side of the substrate, reflected on the back surface side of the substrate, and then incident on the light-receiving element; and
the lens is disposed at a position where the light incident from the light incidence surface is reflected on the main surface side of the substrate or a position where the light incident from the light incidence surface is reflected on the back surface side of the substrate.

22. The light-receiving device according to claim 17, wherein:
an angle between the main surface of the substrate in a region where the light-receiving element is disposed and the light incidence surface is an obtuse angle;
the light incident from the light incidence surface is reflected on the back surface side of the substrate and then incident on the light-receiving element; and
the lens is disposed at a position where the light incident from the light incidence surface is reflected on the back surface side of the substrate or disposed on an incident side of the light incident from the light incidence surface.

23. The light-receiving device according to claim 17, wherein the lens is formed on a bottom surface of a recess on the substrate.

24. The light-receiving device according to claim 17, further comprising:
a metal layer formed covering a surface of the lens.

25. The light-receiving device according to claim 17, wherein:
a plurality of light-receiving elements are disposed on the main surface of the substrate, the plurality of light-receiving elements comprising the light-receiving element.
